(19) United States
(12) Patent Application Publication
(10) Pub. No.: US 2024/0290385 A1
(43) Pub. Date: Aug. 29, 2024

(54) MICROELECTRONIC DEVICES INCLUDING THROUGH-SILICON VIAS, AND RELATED MEMORY DEVICES AND ELECTRONIC SYSTEMS

(71) Applicant: Micron Technology, Inc., Boise, ID (US)

(72) Inventors: James E. Davis, Meridian, ID (US); Shyam Surthi, Boise, ID (US); Martin W. Popp, Meridian, ID (US); KangYoul Lee, Sunnyvale, CA (US); Yui Shimizu, San Jose, CA (US)

(21) Appl. No.: 18/409,702

(22) Filed: Jan. 10, 2024

Related U.S. Application Data
(60) Provisional application No. 63/486,543, filed on Feb. 23, 2023.

(51) Int. Cl. G11C 16/04; H01L 23/528

(52) U.S. Cl. CPC G11C 16/0483; H01L 23/5283

(57) ABSTRACT

A microelectronic device comprises, a control circuitry structure comprising an active region including control logic circuitry at least partially within a semiconductive material; a bond pad on a backside of the control circuitry structure; a conductive contact vertically extending from the bond pad, through the semiconductive material, and to the control logic circuitry; and a dielectric-filled slit vertically extending into the semiconductive material and horizontally circumscribing the conductive contact, portions of the semiconductive material horizontally interposed between the conductive contact and the dielectric-filled slit. Additional microelectronic devices, memory devices, microelectronic device packages, and electronic systems are also described.

### CROSS-REFERENCE TO RELATED APPLICATION

This application claims the benefit under 35 U.S.C. § 119(e) of U.S. Provisional Patent Application Ser. No. 63/486,543, filed Feb. 23, 2023, the disclosure of which is hereby incorporated herein in its entirety by this reference.

### TECHNICAL FIELD

The disclosure, in various embodiments, relates generally to the field of microelectronic device design. More specifically, the disclosure relates to microelectronic devices including through-silicon vias, and related to memory devices and electronic systems.

### BACKGROUND

Microelectronic devices often require complex external interconnection between memory devices and other devices such as test or connected devices. Memory devices are generally provided as internal integrated circuits in computers or other electronic devices, and one type of memory devices includes, but is not limited to, volatile memory devices. One type of volatile memory device is a “not and” (NAND) logic-based memory device. A NAND logic-based memory device may include a 3-dimensional (3D) memory array including tiered strings of memory cells arranged in horizontal rows extending in a first horizontal direction and columns extending in a second horizontal direction.

Control logic devices within a base control logic structure associated with a memory array of a 3D NAND memory device, have been used to control operations on the strings of memory cells of the 3D NAND memory device. Further, testing of the control logic as well as the strings of 3D NAND memory cells, can be done through access pads. Unfortunately, testing has challenges of interconnectivity access.

### BRIEF DESCRIPTION OF THE DRAWINGS

FIG. 1 is a simplified transverse cross-section elevation view of a microelectronic device, in accordance with embodiments of the disclosure.

FIG. 1A is a schematic depicting dielectric-filled slits surrounding a through-silicon via included in the microelectronic device of the conductive contact illustrated in FIG. 1, according to several embodiments.

FIG. 2 is a simplified, top plan view of a portion of the microelectronic device depicted in FIG. 1, in accordance with embodiments of the disclosure.

FIG. 3 is a simplified, partial transverse cross-section elevation view of a microelectronic device, in accordance with additional embodiments of the disclosure.

FIG. 4 is a simplified, partial transverse cross-section elevation of a microelectronic device, in accordance with further embodiments of the disclosure.

FIG. 5 is a simplified, top plan view of a portion of the microelectronic device depicted in FIG. 4, in accordance with embodiments of the disclosure.

FIG. 6 is a simplified, partial transverse cross-section elevation view of a microelectronic device, in accordance with yet further embodiments of the disclosure.

FIG. 7 is a simplified, top plan view of a portion of the microelectronic device depicted in FIG. 6, in accordance with embodiments of the disclosure.

FIG. 8 is a simplified, top plan view of a portion of a microelectronic device, in accordance with embodiments of the disclosure.

FIG. 9 is a simplified, top plan view of a portion of a microelectronic device, in accordance with embodiments of the disclosure.

FIG. 10 is a simplified, partial transverse elevational view of an integrated circuit package, in accordance with embodiments of the disclosure.

FIG. 11 is a simplified, partial transverse cross-section elevation view of a microelectronic device, in accordance with yet still further embodiments of the disclosure.

FIG. 12 is a block diagram of an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round or curved may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory; conventional non-volatile memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fc), ruthenium (Ru), osmium (Os), cobalt (Co), rhodium (Rh), iridium (Ir), nickel (Ni), palladium (Pa), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In₁₋ₓAs_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

As used herein, the term “integrated circuit” or “integrated-circuit device” may refer to a “microelectronic device” or a “nanoelectronic device,” each of which may be tied to a critical dimension exhibited by inspection. The term “integrated circuit” includes without limitation a memory device, as well as other devices (e.g., semiconductor devices) which may or may not incorporate memory. The term “integrated circuit” may include without limitation a logic device. The term “integrated circuit” may include without limitation a processor device such as a central-processing unit (CPU) or a graphics-processing unit (GPU). The term “integrated circuit” may include without limitation or a radiofrequency (RF) device. Further, an “integrated-circuit” device may incorporate memory in addition to other functions such as, for example, a so-called “system on a chip” (SoC) including a processor and memory, or an integrated-circuit device including logic and memory. Further, an “integrated-circuit” device may incorporate memory in addition to other functions such as, for example, a so-called “disaggregated device” where distinct integrated-circuit components are associated to produce the higher function such as that performed by an SoC, including a processor alone, a memory alone, a processor and a memory, or an integrated-circuit device including logic and memory.

As used herein, the term “substrate” means and includes a material (e.g., a base material) or construction upon which additional materials are formed. The substrate may be a semiconductor substrate. The substrate may be a base semiconductor material on a supporting structure, a metal electrode, or a semiconductor substrate having one or more materials, layers, structures, or regions formed thereon. The materials on the semiconductor substrate may include, but are not limited to, one or more of semiconductor materials, insulating materials, and conductive materials. The substrate may be a conventional silicon substrate or other bulk substrate comprising a layer of semiconductor material. As used herein, the term “bulk substrate” means and includes not only silicon wafers, but also silicon-on-insulator (“SOI”) substrates. The “bulk substrate” may be a SOI substrate such as a silicon-on-sapphire (“SOS”) substrate. The “bulk substrate” may be a SOI substrate such as a silicon-on-glass (“SOG”) substrate. The “bulk substrate” may include epitaxial layers of silicon on a base semiconductor foundation. The “bulk substrate” may include other semiconductor and/or optoelectronic materials. The semiconductor and/or optoelectronic materials may, for example, include one or more of silicon-germanium containing materials, germanium-containing materials, silicon-carbide containing materials, gallium arsenide-containing materials, gallium nitride-containing materials, and indium phosphide-containing materials. The substrate may be doped or undoped.

As used herein, the term “mounting substrate” means and includes structures that are configured to accept an integrated-circuit device. The mounting substrate may be a silicon bridge that is configured to connect more than on integrated-circuit device. The mounting substrate may be a package board that directly contacts an integrated circuit device such as a bare die containing a central-processing unit. The package board may be mounted on a printed wiring board (PWB). The mounting substrate may be a printed wiring board onto which at least one integrated circuit device and/or package board are mounted. The mounting substrate may include a disaggregated device. Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

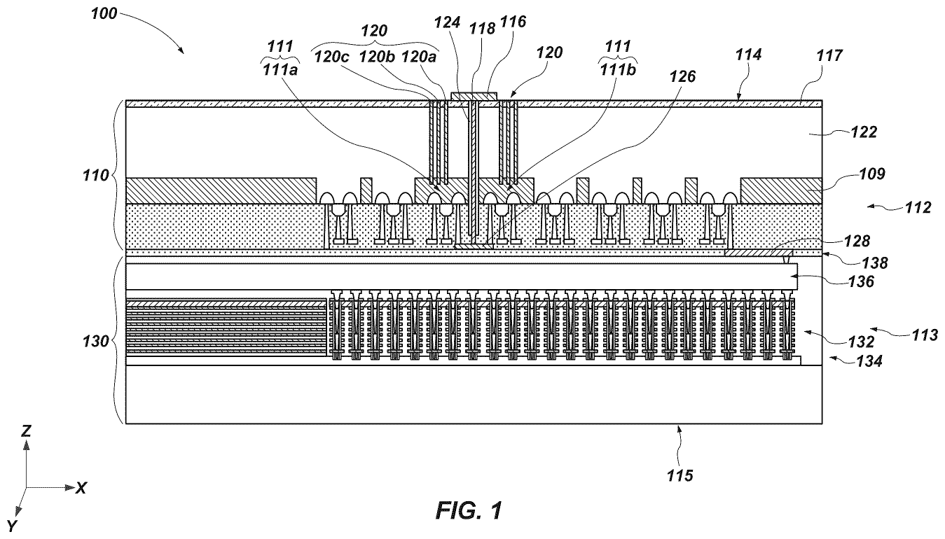

FIG. 1 is a simplified transverse cross-section elevation view of a microelectronic device 100 (e.g., a memory device, such as a 3D NAND Flash memory device) including a control circuitry structure 110 (e.g., a control circuitry wafer) including control logic devices including control logic circuitry, such as complementary metal-oxide-semiconductor (CMOS) circuitry; and a memory array structure 130 (e.g., a memory array wafer) including at least one array of memory cells. In some embodiments, the microelectronic device 100 may be characterized as having a “CMOS above Array” (“CaA”) configuration.

Still referring to FIG. 1, the control circuitry structure 110 may be attached (e.g., bonded) to the memory array structure 130 in a so-called “wafer-to-wafer” (W2 W) configuration. The control circuitry structure 110 includes an active region 112 that having control logic devices individually including transistors 111 and additional circuitry; and a backside 114 opposite the active region 112. The active region 112 may be partially positioned within a base semiconductor material 122 (e.g., bulk silicon material) of the microelectronic device 100 located within the control circuitry structure 110. The control logic devices of the active region 112 may be configured to control various operations of other features (e.g., strings of memory cells within the memory array structure 130) of the microelectronic device 100. As a non-limiting example, the active region 112 of the control circuitry structure 110 may include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., string drivers), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, multiplexing (MUX) devices, error checking and correction (ECC) devices, self-refresh/wear leveling devices, and other chip/deck control circuitry. The control logic devices of the active region 112 of the control circuitry structure 110 may be coupled to features (e.g., routing structures, contact structures, memory cells) within the memory array structure 130 of the microelectronic device 100.

Still referring to FIG. 1, the memory array structure 130 has an additional active region 113. The additional active region 113 includes an array region 134 having strings of memory cells 132 therein; and a contact region horizontally neighboring the array region 134 and including staircase structures therein. The memory array structure 130 also includes an additional backside 115 opposite the additional active region 113. With the active region 112 of the control circuitry structure 110 vertically positioned proximate to the additional active region 113 of the memory array structure 130, the microelectronic device 100 may be considered to have a so-called “face-to-face” (F2F) configuration.

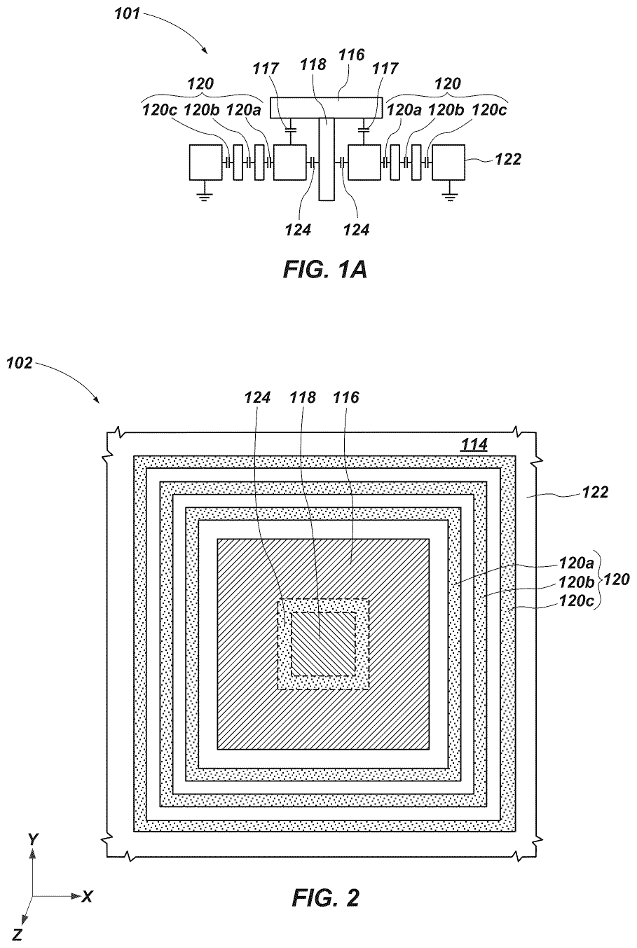

Still referring to FIG. 1, a bond pad 116 on the backside 114 of the control circuitry structure 110 is coupled to circuitry of the active region 112 of the control circuitry structure 110 by way of at least one conductive contact 118 vertically extending through the base semiconductor material 122. As shown in FIG. 1, in some embodiments, an isolation material 117 (e.g., a dielectric material, such as a dielectric oxide material) is interposed between the bond pad 116 and the base semiconductor material 122. If the base semiconductor material 122 comprises bulk silicon, the at least one conductive contact 118 may comprise a so-called “through silicon contact” (TSC) structure and/or a so-called “through silicon via” (TSV) structure. In addition, the control circuitry structure 110 includes dielectric-filled slits 120 within the base semiconductor material 122 and horizontally surrounding the conductive contact 118. In some embodiments, the dielectric-filled slits 120 comprise slits filled with silicon oxide. In such embodiments, the silicon oxide may be formed by oxidizing silicon of the base semiconductor material 122. The several dielectric-filled slits 120 vertically underlie the bond pad 116 and horizontally surround the conductive contact 118, such that in top view (e.g., FIG. 2) the dielectric-filled slits 120 appear as concentric “frame” (2D view) form factors, or concentric “fence” (3D view) form factors that horizontally surround the conductive contact 118. As illustrated, the several dielectric-filled slits 120 may include a first dielectric-filled slit 120a, a second dielectric-filled slit 120b having portions horizontally spaced apart from and horizontally extending parallel to the first dielectric-filled slit 120a, and at least one subsequent dielectric-filled slit 120c (in this illustration, a third dielectric-filled slit 120c) having portions horizontally spaced apart from and horizontally extending parallel to the second dielectric-filled slit 120b. The multiple (e.g., at least two (2)) dielectric-filled slits 120 create a series capacitance with respect to capacitance experienced at each of the bond pad 116 and the conductive contact 118, such that the series capacitance reduces overall capacitance. In some embodiments, only two (2) dielectric-filled slits 120 vertically underlie the bond pad 116 and horizontally surround the conductive contact 118. In additional embodiments, three dielectric-filled slits 120 vertically underlie the bond pad 116 and horizontally surround the conductive contact 118 below the bond pad 116. In further embodiments, up to five (5) dielectric-filled slits 120 vertically underlie the bond pad 116 and horizontally surround the conductive contact 118. Further, useful high-speed interconnectivity is available between the bond pad 116 and the circuitry of the active region 112 that facilitates functions such as testing and die-to-die data communication interconnections.

Communication between the conductive contact 118 and circuitry of the control circuitry structure 110 may be facilitated by way of routing structures 126, such as traces. As illustrated, an individual routing structure 126 may be coupled to an individual conductive contact 118 and to two (2) neighboring transistors 111. Several transistors 111 may be included in the sub-circuitry and other circuitry of the control circuitry structure 110. In some embodiments, the conductive contact 118 vertically extends through the base semiconductor material 122, and the conductive contact 118 couples to at least one of a first transistor 111a and a second transistor 111b spaced apart from the conductive contact 118. Insulative material 109 may be horizontally interposed between horizontally neighboring transistors 111.

Still referring to FIG. 1, the control circuitry structure 110 further includes a dielectric liner 124 substantially surrounding and vertically extending across sidewalls of the conductive contact 118. The dielectric liner 124 may be interposed between the base semiconductor material 122 and the conductive contact 118. In some embodiments, the dielectric liner 124 is formed of and includes SiO₂.

The memory array structure 130 is illustrated in simplified detail, with the strings of memory cells 132 depicted in the array region 134. In addition, an interconnect region 136 is illustrated in simplified form. The interconnect region 136 may, in part, be formed of and include semiconductor material (e.g., silicon). A configuration of the interconnect region 136 may facilitate electrical communication between staircase structures within staircase regions and the strings of memory cells 132 within the array region 134, as well as electrical communication between the strings of memory cells 132 of the array region 134 and circuitry of the control circuitry structure 110. In some embodiments, electrical communication between features (e.g., materials, structures, devices) of the array region 134 and additional features (e.g., additional materials, additional structures, additional devices) of the control circuitry structure 110 is achieved by way of an interface 138 with interconnect structures 128. The interface 138 may be between materials (e.g., dielectric material, such as oxide materials, and conductive materials, such as metallic material) of the control circuitry structure 110 and the memory array structure 130 and may or may not be visible upon inspection. In some embodiments, the interface 138 is a bond (e.g., oxide-oxide bond, metal-metal bond) location between the control circuitry structure 110 and the memory array structure 130. The control circuitry structure 110 may be bonded to the memory array structure 130 without a bond line. Where the conductive contact 118 is vertically above the array region 134, the configuration of the bond pad 116 and the conductive contact 118 may be referred to as “TSV bond pad over array.”

FIG. 1A is a schematic description 101 of an effect of the several dielectric-filled slits 120 that surround the conductive contact 118 in relation to the bond pad 116 that is at the backside 114 of the control circuitry structure as seen in FIG. 1, according to several embodiments. The backside 114 may have the isolation material 117 (represented in FIG. 1A by capacitance effect symbols), the base semiconductor material 122, the dielectric-filled slits 120 (e.g., dielectric-filled slits 120a, 120b, 120c), and the dielectric liner 124. The isolation material 117 may have a thickness within a range of from about 100 nanometer (nm) (about 0.1 micrometer (μm)) to about 4,000 nm (about 4 μm), such as from about 0.1 μm to about 3 μm. In some embodiments, the base semiconductor material 122 has a thickness within a range of from about 200 nm to about 3,000 nm (about 0.2 μm to about 3.0 μm). In some embodiments, the base semiconductor material 122 has a thickness within a range of from about 3.0 μm to about 5.0 μm. In some embodiments, the base semiconductor material 122 may have a thickness within a range of from about greater than 5.0 μm to about 15 μm, such as from about 5.0 μm to about 14 μm, or from about 11 μm to about 13 μm. The dielectric-filled slits 120 may be a silicon-oxide-filled and may each have a thickness within a range of from about 0.1 μm to about 2 μm, such as from about 0.1 μm to about 1.5 μm. The conductive contact 118 may be surrounded by the dielectric liner 124 of silicon oxide that has a lateral thickness within a range of from about 0.1 μm to about 2 μm, such as from about 0.5 μm to about 1.0 μm.

The effects of multiple dielectric-filled slits 120 (e.g., at least two (2)), create a series capacitance with respect to capacitance experienced at each of the bond pad 116 and the conductive contact 118, such that the series capacitance reduces overall capacitance. Further, useful high-speed interconnectivity (e.g., greater than or equal to one (1) GigaTransfers per second (GT/s)) is available between the bond pad 116 and the circuitry of the active region 112 that facilitates functions such as testing and die-to-die data communication interconnections. Table 1 below illustrates several non-limiting example results where two (2) conductive contacts are used with varying of dielectric-filled slits 120.

TABLE 1

| | | 1 | 2 | 3 |
|---|---|---|---|---|
| | No | dielectric | dielectric | dielectric |
| Pad on CMOS | slit | slit | slits | slits |
| % of cap. limit | 11 | 9.1 | 7.5 | 6 |

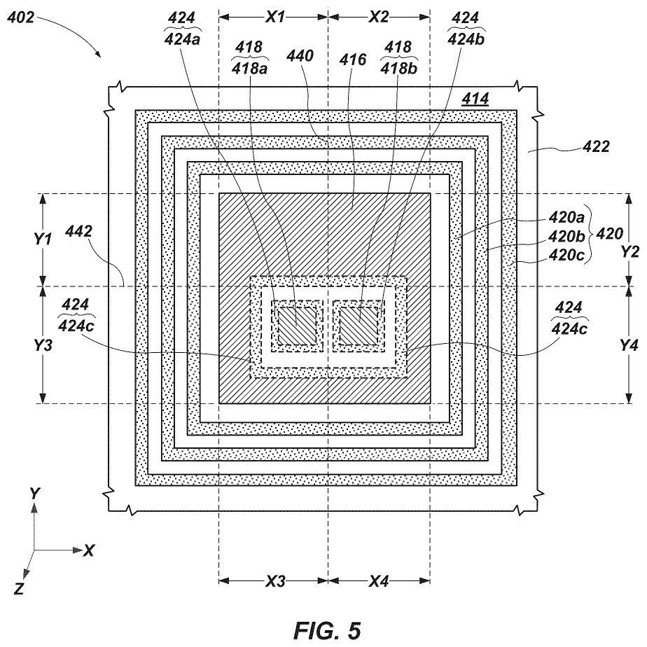

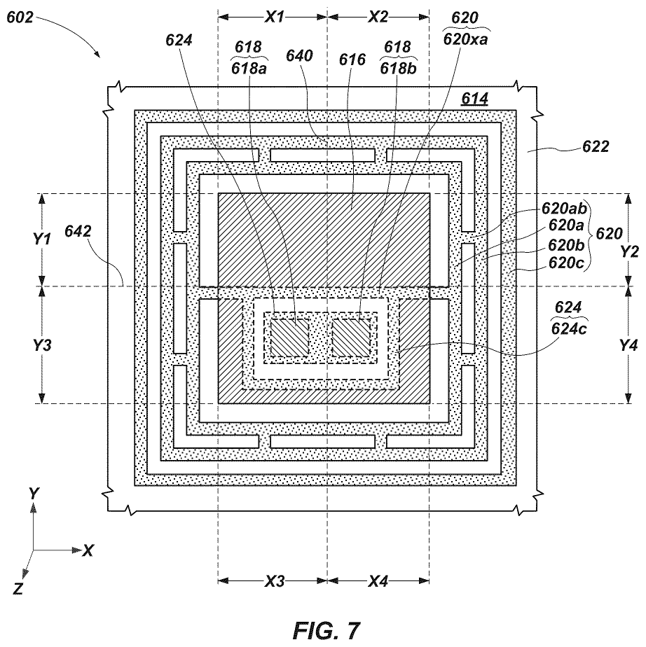

FIG. 2 is a simplified, top plan view 102 of a portion of the microelectronic device 100 shown in FIG. 1. FIG. 2 shows the configurations of the bond pad 116, the conductive contact 118, and the several dielectric-filled slits 120 (e.g., dielectric-filled slits 120a, 120b and 120c) depicted in FIG. 1. The bond pad 116 and neighboring structures, including several dielectric-filled slits 120a, 120b and 120c, are illustrated. The CMOS die backside 114, the dielectric-filled slits 120a, 120b and 120c, and the base semiconductor material 122 are represented proximate the bond pad 116. The conductive contact 118 and the dielectric liner 124 are illustrated using dashed lines as they are below (Z-direction) the bond pad 116. In some embodiments, a horizontal center of the conductive contact 118 is substantially aligned with a horizontal center of the bond pad 116 (see, e.g., FIGS. 2, 8 and 9). In additional embodiments, a horizontal center of the conductive contact 118 is of the bond pad 116 (see, e.g., FIGS. 5 and 7).

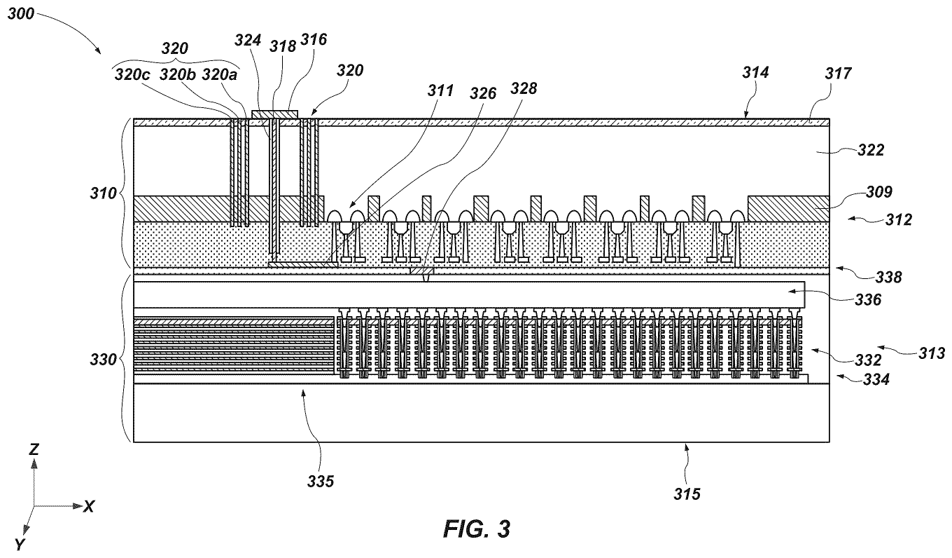

FIG. 3 is a simplified, partial transverse cross-section elevation view of a microelectronic device 300, according to some embodiments. The microelectronic device 300 may include a control circuitry structure 310, a memory array structure 330, and at least one conductive contact 318 (e.g., TSC structure, TSV structure) is located above an array edge region 335 of the memory array structure 330. Before discussing FIG. 3 in further details, it will be understood that throughout FIGS. 3 through 10 and the associated description, features (e.g., regions, materials, structures, devices) functionally similar to previously described features (e.g., previously described materials, structures, devices) are referred to with similar reference numerals incremented by 100. To avoid repetition, not all features shown in FIGS. 3 through 10 are described in detail herein. Rather, unless described otherwise below, a feature in one or more of FIGS. 3 through 10 designated by a reference numeral that is a 100 increment of the reference numeral of a feature previously described with reference to a preceding one or more of FIGS. 1 through 9 will be understood to be substantially similar to, and have substantially the same advantages as, the previously described feature. In addition, for clarity and case of understanding the drawings and related description, some features (e.g., structures, materials, regions, devices) previously described with reference to one or more of FIGS. 3 through 10 are not depicted in FIGS. 3 through 10. However, unless described otherwise below, it will be under that any features of the microelectronic device 100 described with reference to one or more of FIGS. 1 through 10 may be included in any of the different configurations described herein below with reference to one or more other of FIGS. 1 through 10.

Referring to FIG. 3, the control circuitry structure 310 vertically overlies (Z-direction) a memory array structure 330. The control circuitry structure 310 includes an active region 312 that includes transistors, sub-circuitry and other circuitry; and the control circuitry structure 310 includes a backside 314. The active region 312 may be contained within a base structure of the microelectronic device 300 within the control circuitry structure 310, and the base structure may include at least one control logic region including control logic devices configured to control various operations of other features (e.g., strings of memory cells 332 within an array region 334) of the microelectronic device 300.

A bond pad 316 on the backside 314 may be coupled to circuitry of the active region 312 of the control circuitry structure 310 by way of two (2) conductive contacts 318 (e.g., conductive contacts 318a and 318b (not shown)), with conductive contacts 318a and 318b being arranged among dielectric-filled slits 320 (e.g., dielectric-filled slits 320a, 320b and 320c) extending through base semiconductor material 322 of the control circuitry structure 310. The several dielectric-filled slits 320 surround the conductive contacts 318 below (Z-direction) the bond pad 316, such that in a top-down view, concentric “frame” (2D view) form factors, or concentric “fence” (3D view) form factors of dielectric-filled slits 320 surround the conductive contacts 318. Consequently, the series of dielectric-filled slits 320 (at least two (2)) facilitate series capacitance with respect to capacitance experienced at each of the bond pad 316 and the conductive contacts 318, such that the series capacitance reduces overall capacitance. Further, useful high-speed interconnectivity is available between the bond pad 316 and the circuitry of the active region 312 that facilitates functions such as testing and die-to-die data communication interconnections.

Still referring to FIG. 3, and in comparison to embodiments illustrated in FIG. 1, the conductive contacts 318 (or only one of them being present), extend through the base semiconductor material 322 vertically overlying and within a horizontal area of an array edge region 335 of the array region 334 of the memory array structure 330. In some embodiments, one or more of the conductive contacts 318 (e.g., only one, if only one is present), extend into the circuitry of the active region 312 at or proximate the array edge region 335, to simplify interconnection geometries between the control circuitry structure 310 and the memory array structure 330 proximate the conductive contacts 318. Where the conductive contacts 318 extend above the control circuitry structure 310 at the array edge region 335, the location of the conductive contact 318 may be referred to as contacts outside the array (e.g., “TSV pads 316 outside the array region 334”). In some embodiments, the conductive contacts 318a and 318b may be used in combination with the conductive contact 118 previously described with reference to FIG. 1. For example, the conductive contact 118 (FIG. 1) may be located away from the array edge region 335 (e.g., more proximate a horizontal center of the array region 134), and one or more of the conductive contacts 318 (e.g., only one, if only one is present) may be present and located within or relatively more proximate to a horizontal area of the array edge region 335.

Still referring to FIG. 3, one or more of the conductive contacts 318 (e.g., only one, if only one is present) may individually be surrounded by a dielectric liner 324. In some embodiments, only two dielectric-filled slits 320 (e.g., dielectric-filled slits 320a and 320b) below the bond pad 316, surround conductive contacts 318a and 318b (not shown). In some embodiments, three dielectric-filled slits 320 (e.g., dielectric-filled slits 320a, 320b and 320c) below the bond pad 316 surround the conductive contacts 318 below the bond pad 316. In some embodiments, up to five (5) dielectric-filled slits 320 below the bond pad 316 surround conductive contacts 318a and 318b (not shown). Communication between the conductive contacts 318 and the circuitry of the control circuitry structure 310 may include interconnect structures 326, such as traces. In some embodiments, the two conductive contacts 318 are ganged from the bond pad 316 to a single trace interconnect structure 326. Several transistors may be included in the sub-circuitry and other circuitry of the control circuitry structure 310. In some embodiments, the conductive contacts 318 penetrate the base semiconductor material 322, and the conductive contacts 318 couple to at least one transistor 311 above the array edge region 335. The transistor 311 may be spaced apart from and proximate to the conductive contacts 318, and several transistors 311 may be separated by insulative material 309.

Similar to the memory array structure in FIG. 1, the memory array structure 330 is illustrated in simplified detail, with the strings of memory cells 332 depicted in the array region 334. Further the memory array structure 330 includes an additional backside 315 that is opposite the additional active region 313. In addition, an interconnect region 336 is illustrated in simplified form. A configuration of the interconnect region 336 may facilitate electrical communication between staircase structures within staircase regions and the strings of memory cells 332 within the array region 334, as well as electrical communication between the strings of memory cells 332 of the array region 334 and circuitry of the control circuitry structure 310. In some embodiments, electrical communication between features (e.g., materials, structures, devices) of the array region 334 and additional features (e.g., additional materials, additional structures, additional devices) of the control circuitry structure 310 is achieved by way of an interface 338 with interconnect structures 328. The interface 338 may be between materials (e.g., dielectric material, such as oxide materials; conductive materials, such as metallic material) of the control circuitry structure 310 and the memory array structure 330 and may or may not be visible upon inspection.

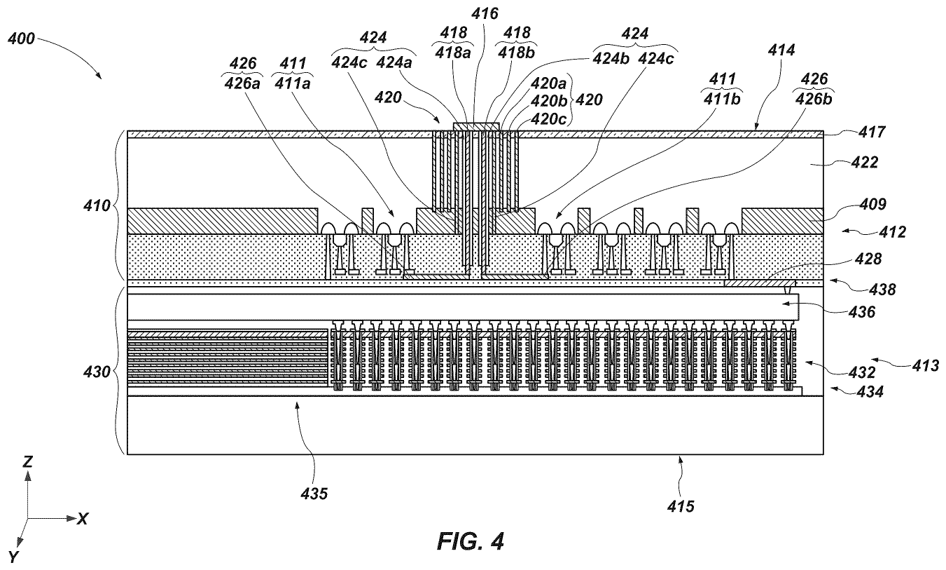

FIG. 4 is a simplified, partial transverse cross-section elevation of a microelectronic device 400, according to some embodiments. The microelectronic device 400 includes a control circuitry structure 410 located vertically over (Z-direction) a memory array structure 430. The control circuitry structure 410 includes an active region 412 that includes transistors, sub-circuitry and other circuitry, and the control circuitry structure 410 includes a backside 414. The active region 412 may be contained within a base structure within the control circuitry structure 410, and the base structure may include at least one control logic region including control logic devices configured to control various operations of other features (e.g., strings of memory cells 432 within an array region 434) of the microelectronic device 400.

A bond pad 416 on the backside 414 is coupled to circuitry of the active region 412 of the control circuitry structure 410 with two (2) conductive contacts 418 (e.g., first and second conductive contacts 418a and 418b), and the conductive contacts 418 are arranged among dielectric-filled slits 420 (e.g., dielectric slots 420a, 420b and 420c) extending through a base semiconductor material 422 of the control circuitry structure 410. The several dielectric-filled slits 420 surround the two conductive contacts 418 below (Z-direction) the bond pad 416. In comparison to at least partially symmetrically located conductive contacts of the two conductive contacts 318 shown in FIG. 3, in an embodiment, the two conductive contacts 418 are in separate dielectric liners 424 (e.g., dielectric liners 424a and 424b). Further, horizontal centers of the conductive contacts 418 in the Y-direction are horizontally offset from a horizontal center in the Y-direction of the bond pad 416 (see FIG. 5), such that in top view, asymmetrical “frame” (2D view) form factors, or asymmetrical “fence” (3D view) form factors of dielectric-filled slits 420 surround the conductive contacts 418. Consequently, the series of dielectric-filled slits 420 (at least two (2)), facilitates a series capacitance with respect to capacitance experienced at each of the bond pad 416 and the conductive contacts 418, such that the series capacitance reduces overall capacitance. Further, useful high-speed interconnectivity is available between the bond pad 416 and the circuitry of the active region 412 that facilitates functions such as testing and die-to-die data communication interconnections.

Still referring to FIG. 4, and in comparison to embodiments illustrated in FIG. 3, a first conductive contact 418a is surrounded by a first dielectric liner 424a, and the second conductive contact 418b is surrounded by second dielectric liner 424b. Additionally, in an embodiment, the first conductive contact 418a is directly coupled to a first interconnect structure 426a that extends to selected circuitry within the active region 412 of the control circuitry structure 410; and the second conductive contact 418b is directly coupled to a second interconnect structure 426b that extends to other selected circuitry within the active region 412. In some embodiments, during testing operations for the microelectronic device 400, a multiplexing (MUX) technique is used at the bond pad 416, where data exchange is alternated among the first conductive contact 418a and the second conductive contact 418b.

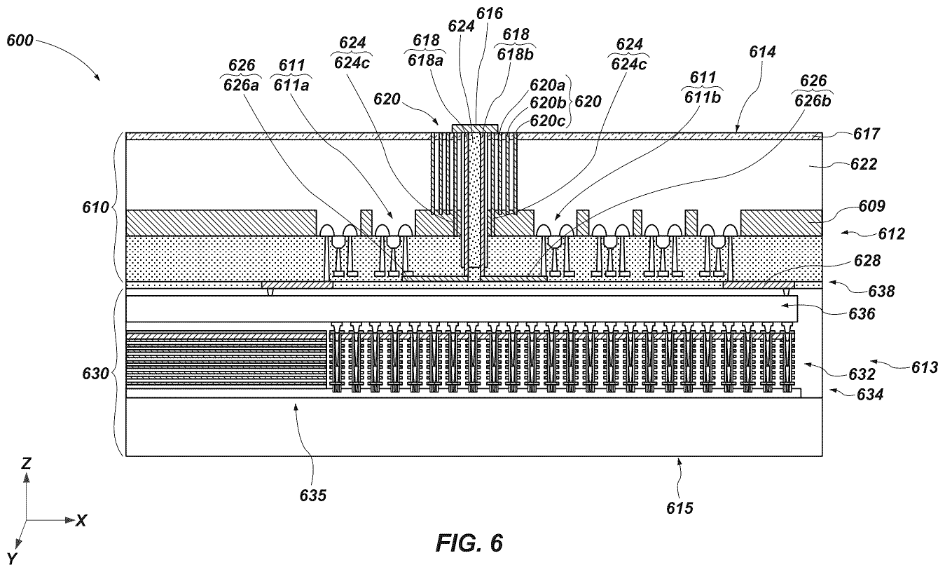

Still referring to FIG. 4, a hybrid structure that in part acts as a third dielectric liner 424c, and that in part acts as a subsequent dielectric-filled slit (see also FIG. 5), may enclose the conductive contacts 418. The third dielectric liner 424c (see also FIG. 6) may vertically extend relatively deeper (Z-direction) into the base semiconductor material 422. In some embodiments, each of the several dielectric-filled slits 420 and the third dielectric liner 424c all extend into the active region 412. In additional embodiments, one or more (e.g., each) of the several dielectric-filled slits 420 and the third dielectric liner 424c vertically terminate above the active region 412. Processing of selected depths may be done depending upon useful series capacitance reduction amounts. In some embodiments, similar to the location of the conductive contacts 318 in FIG. 3, the several conductive contacts 418 may be located vertically above and within a horizontal area of the array edge region 435 of the array region 434.

Still referring to FIG. 4, in some embodiments, only two dielectric-filled slits 420 below the bond pad 416 may surround the conductive contacts 418. In additional embodiments, three dielectric-filled slits 420 below the bond pad 416 surround the conductive contacts 418. In further embodiments, up to five dielectric-filled slits 420 below the bond pad 416 surround at least two conductive contacts 418.

Communication between the conductive contacts 418 and the circuitry of the control circuitry structure 410 may include interconnect structures 426 (e.g., interconnect structures 426a and 426b), such as traces. Several transistors 411 (e.g., first and second transistors 411a and 411b) may be included in the sub-circuitry and other circuitry of the control circuitry structure 410. In some embodiments, the conductive contacts 418 penetrate the base semiconductor material 422. The conductive contacts 418 may couple to at least one of a first transistor 411a and a second transistor 411b that may neighbor the conductive contacts 418. The transistors 411 may be separated by insulative material 409. In comparison to some embodiments, more insulative material 409 may space apart the conductive contacts 418 from neighboring transistors 411 than, the insulative material 109 in FIG. 1 spaces apart the conductive contact 118 in FIG. 1. In some embodiments, the first transistor 411a is in an NMOS transistor of the control circuitry structure 410, and the second transistor 411b is in a PMOS transistor of the control circuitry structure 410.

Similar to the memory array structure in FIGS. 1 and 3, the memory array structure 430 is illustrated in simplified detail, with the strings of memory cells 432 depicted in the array region 434. Further, the memory array structure 330 includes an additional backside 415 opposite the additional active region 413, and an interconnect region 436.

FIG. 5 is a simplified, top plan view 402 of a portion of the microelectronic device 400 shown in FIG. 4. FIG. 5 shows configurations of the bond pad 416, the conductive contacts 418 (e.g., the first conductive contact 418a, the second conductive contact 418b), and the several dielectric-filled slits 420. The backside 414 of the control circuitry structure 410 and the base semiconductor material 422 are represented proximate the bond pad 416, and the conductive contacts 418 and the dielectric liners 424 are illustrated using dashed lines. In some embodiments, the locations of the first conductive contact 418a and the second conductive contact 418b may be asymmetrical with relation to a geometric center of the bond pad 416. In some embodiments, the bond pad 416 may be delineated in quarters, and locations of the conductive contacts 418 may be varied depending upon wiring densities and complexities. In some embodiments, a first symmetry line 440 is used with a second symmetry line 442. The first symmetry line 440 and the second symmetry line 442 may bilaterally bisect the bond pad 416 at a geometric center in a first horizontal direction (Y-direction) and a second horizontal direction (X-direction), respectively. Additionally, a horizontal area of the bond pad 416 may be divided into quarters by the first symmetry line 440 and the second symmetry line 442. The location of a given conductive contact 418 may be identified with relation to geometric center of the bond pad 416. For example, a first direction, first lateral distance Y1 and a first direction, a second lateral distance Y2 may be used to locate a given conductive contact 418 defined with respect to one lateral dimension of the bond pad 416 on one side of the second symmetry line 442. Similarly, a first direction, third lateral distance Y3 and a first direction, fourth lateral distance Y4 may be used to locate a given conductive contact 418 defined with respect to the same lateral dimension of the bond pad 416 on another side of the second symmetry line 442. Furthermore, a second direction, first lateral distance X1 and a second direction, second lateral distance X2 may be used to locate a given conductive contact 418 defined with respect to one lateral dimension of the bond pad 416 on one side of the first symmetry line 440, and a second direction, third lateral distance X3 and a second direction, fourth lateral distance X4 may each also be used locate a given conductive contact 418 with respect to another lateral dimension of the bond pad 416 on another side of the first symmetry line 440.

Still referring to FIG. 5, the first conductive contact 418a may be located within a third quarter of the footprint of the bond pad 416. Horizontal boundaries of the third quarter may be defined by the first direction third lateral distance Y3 and the second direction third lateral distance X3. In addition, the second conductive contact 418b may be located within a fourth quarter of the footprint of the bond pad 416. Horizontal boundaries of the fourth quarter may be defined by, as by the first direction fourth lateral distance Y4 and the second direction fourth lateral distance X4. As depicted in FIG. 5, each of the first conductive contact 418a and the second conductive contact 418b are offset from the second symmetry line 442. In some embodiments, the first conductive contact 418a and the second conductive contact 418b horizontally overlap one another in the Y-direction. In additional embodiments, the first conductive contact 418a and the second conductive contact 418b are horizontally offset from one another in the Y-direction. For example, at least one conductive contact 418 may be positioned to one side of the second symmetry line 442, and at least one other conductive contact 418 may be positioned to another side of second symmetry line 442.

FIG. 6 is a simplified, partial transverse cross-section elevation view of a microelectronic device 600, according to some embodiments. The microelectronic device 600 includes a control circuitry structure 610 located vertically over (Z-direction) a memory array structure 630. At least two conductive contacts 618 (e.g., conductive contacts 618a and 618b) vertically extend through base semiconductor material 622, and the at least two conductive contacts 618 are arranged within a single (e.g., only one) dielectric liner 624. The control circuitry structure 610 includes an active region 612 that includes transistors, sub-circuitry, and other circuitry. The control circuitry structure 610 also includes a backside 614 that is opposite the active region 612. The active region 612 may be contained within a base structure of the microelectronic device 600 within the control circuitry structure 610, and the base structure may include at least one control logic region including control logic devices configured to control various operations of other features (e.g., strings of memory cells 632 within an array region 634) of the microelectronic device 600.

A bond pad 616 on the backside 614 may be coupled to circuitry of the active region 612 of the control circuitry structure 610 by way of two (2) conductive contacts 618, and the conductive contacts 618 are arranged among dielectric-filled slits 620 (e.g., dielectric-filled slits 620a, 620b and 620c) vertically extending through the base semiconductor material 622 of the control circuitry structure 610. The several dielectric-filled slits 620 surround the two conductive contacts 618 below (Z-direction) the bond pad 616. In an embodiment, the two conductive contacts 618, in comparison to the two conductive contacts 418 in FIG. 4, are configured within a single dielectric liner 624. In some embodiments, horizontal centers of the conductive contacts 618 is the Y-direction are horizontally offset from a horizontal center in the Y-direction of the bond pad 616 (see e.g., FIG. 7), such that in top view, asymmetrical “frame” (2D view) form factors, or asymmetrical “fence” (3D view) form factors of dielectric-filled slits 620 surround the conductive contacts 618. Consequently, the series of dielectric-filled slits 620 (at least two (2)), facilitate a series capacitance with respect to capacitance experienced at each of the bond pad 616 and the conductive contacts 618, such that the series capacitance reduces overall capacitance. Further, useful high-speed interconnectivity is available between the bond pad 616 and the circuitry of the active region 612 that facilitates functions such as testing and die-to-die data communication interconnections.

Still referring to FIG. 6 in an embodiment, the first conductive contact 618a is directly coupled to a first interconnect structure 626a that extends to selected circuitry within the active region 612 of the control circuitry structure 610; and the second conductive contact 618b is directly coupled to a second interconnect structure 626b that extends to other selected circuitry within the active region 612. In some embodiments, during testing operations for the microelectronic device 600, a multiplexing (MUX) technique is used at the bond pad 616, where data exchange is alternated among a first conductive contact 618a and a second conductive contact 618b.

Still referring to FIG. 6, a hybrid structure that in part acts as a third dielectric liner 624c, and that in part acts as a subsequent dielectric-filled slit (see also FIG. 7), may enclose the conductive contacts 618. The third dielectric liner 624c may vertically extend relatively deeper (Z-direction) into the base semiconductor material 622. In some embodiments, the several dielectric-filled slits 620 and the third dielectric liner 624c each extend into the active region 612. In additional embodiments, one or more (e.g., each) of the several dielectric-filled slits 620 and the third dielectric liner 624c vertically terminate above the active region 612. Processing of selected depths may be done depending upon useful series capacitance reduction. In some embodiments, similar to the location of the conductive contacts 318 in FIG. 3, the conductive contacts 618 may be located above and within a horizontal area of the array edge region 635 of the array region 634.

Still referring to FIG. 6, in some embodiments, only two dielectric-filled slits 620 below the bond pad 616 surround the conductive contacts 618. In additional embodiments, three dielectric-filled slits 620 below the bond pad 616 surround the conductive contacts 618. In further embodiments, up to five dielectric-filled slits 620 below the bond pad 616 surround at least two conductive contacts 618.

Communication between the conductive contacts 618 and the circuitry of the control circuitry structure 610 may include interconnect structures 626 (e.g., interconnect structures 626a and 626b), such as traces. Several transistors 611 (e.g., first and second transistors 611a and 611b) may be included in the sub-circuitry and other circuitry of the control circuitry structure 610. In some embodiments, the conductive contacts 618 penetrate the base semiconductor material 622. The conductive contacts 618 may couple to at least one of a first transistor 611a and a second transistor 611b that may neighbor the conductive contacts 618, and the transistors 611 may be separated by insulative material 609.

Similar to the memory array structure in FIGS. 1 and 3, the microelectronic device 600 is illustrated in simplified detail, with the strings of memory cells 632 depicted in the array region 634. Further the memory array structure 630 includes an additional backside 615 that is opposite the additional active region 613, and an interconnect region 636.

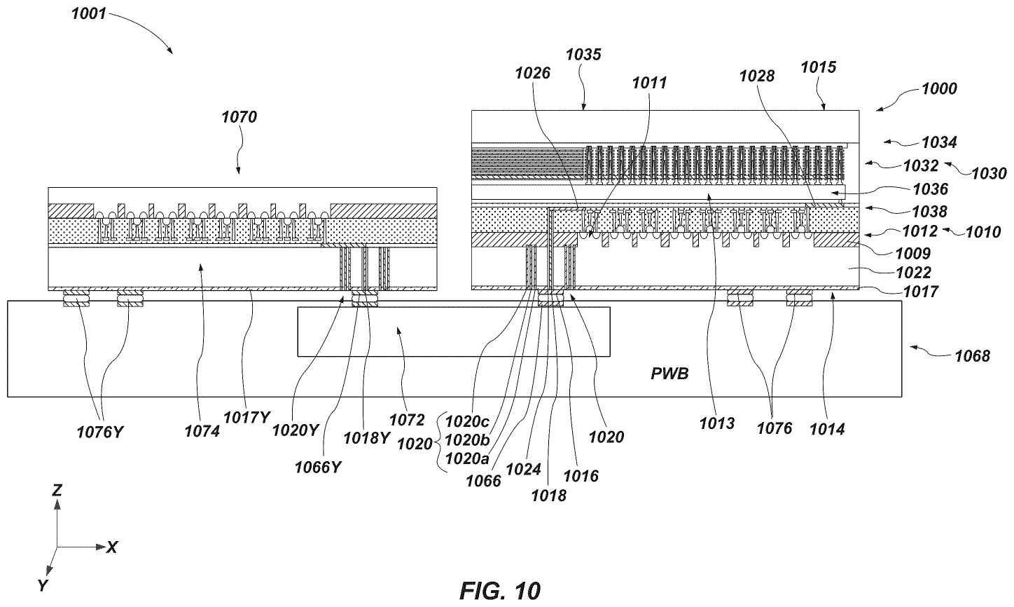

FIG. 7 is a simplified, top plan view 602 of a portion of the microelectronic device 600 shown in FIG. 6. FIG. 7 depicts configurations of the bond pad 616, the conductive contacts 618, the single dielectric liner 624, and the several dielectric-filled slits 620. The backside 614 of the control circuitry structure 610 and the base semiconductor material 622 are represented proximate the bond pad 616, and the conductive contacts 618 are illustrated using dashed lines since they are below the bond pad 616. The several dielectric-filled slits 620 and an intervening dielectric line 620ab, continuous with the dielectric-filled slits 620 may together form a single dielectric-filled structure. In additional embodiments, a subsequent dielectric-filled slit 620c does not communicate with (e.g., is discrete from, is spaced apart from) a neighboring second dielectric-filled slit 620b. In further embodiments, transverse dielectric-filled slit structures 620xa may be continuous with sections of the first dielectric-filled slit 620a below the bond pad 616. In some embodiments, the several additional dielectric-filled slit structures 620ab and 620xa may reduce serial capacitance during test use of the control circuitry structure 610 (FIG. 6), and/or during data transfer use of the microelectronic device 600, such as is illustrated in FIG. 10.

In some embodiments, horizontal centers of each of a first conductive contact 618a and a second conductive contact 618b may be horizontally offset in the Y-direction from a horizontal center of the bond pad 616. In some embodiments, the bond pad 616 may be delineated in quarters and locations of the conductive contacts 618 may be varied depending upon wiring densities and complexities. In some embodiments, a first symmetry line 640 is used with a second symmetry line 642. The first symmetry line 640 and the second symmetry line 642 may bilaterally bisect the bond pad 616 at a geometric center in a first horizontal direction (Y-direction) and a second horizontal direction (X-direction), respectively. Additionally, the horizontal area of the bond pad 616 may be divided into quarters by the first symmetry line 640 and the second symmetry line 642, in a manner similar to that previously described with reference to FIG. 5.

Still referring to FIG. 7, the first conductive contact 618a may be located within a third quarter of the footprint of the bond pad 616. A horizontal area of the third quarter may be defined by the first direction third lateral distance Y3 and the second direction third lateral distance X3. Similarly, the second conductive contact 618b may be located within a fourth quarter of the footprint of the bond pad 616. A horizontal area of the fourth quarter may be defined, as by the first direction fourth lateral distance Y4 and the second direction fourth lateral distance X4. In some embodiments, the first conductive contact 618a and the second conductive contact 618b horizontally overlap one another in the Y-direction. In additional embodiments, the first conductive contact 618a and the second conductive contact 618b are horizontally offset from one another in the Y-direction. For example, at least one conductive contact 618 may be positioned to one side of the second symmetry line 642, and at least one other conductive contact 618 may be positioned to another side of second symmetry line 642.

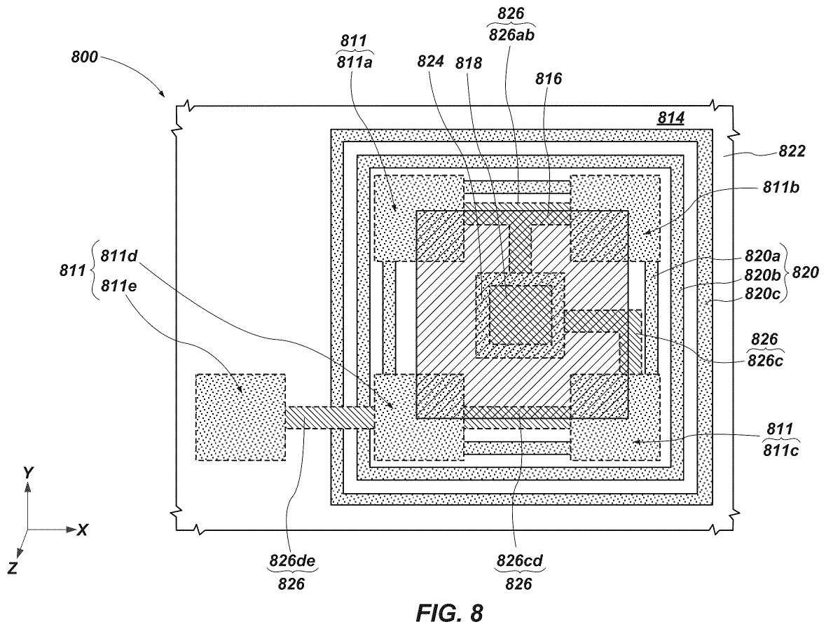

FIG. 8 is a simplified, top plan view of a microelectronic device 800, according to some embodiments. The microelectronic device 800 includes a bond pad 816, a conductive contact 818, several dielectric-filled slits 820 (e.g., dielectric-filled slits 820a, 820b, 820c), and several transistor devices 811. The conductive contact 818 extends from a backside of a control circuitry structure, according to some embodiments. A backside 814 of the control circuitry structure 810 (not shown in this figure), dielectric-filled slits 820a, 820b and 820c, and base semiconductor material 822 are proximate the bond pad 816. The conductive contact 818 and a dielectric liner 824 are illustrated using dashed lines as they are below the bond pad 816.

Still referring to FIG. 8, in some embodiments, the conductive contact 818 is coupled to several spaced apart and neighboring transistors 811, such as a first transistor 811a, a second transistor 811b, a third transistor 811c, and a fourth transistor 811d. Further, in some embodiments, the conductive contact 818 is also coupled to at least one fifth transistor 811e, wherein at least one intervening transistor 811 (e.g., the fourth transistor 811d) horizontally intervenes within the fifth transistor 811e and the conductive contact 818. In some embodiments, the conductive contact 818 is coupled in parallel to two transistors 811 (e.g., first transistor 811a, a second transistor 811b) by one or more interconnect structures 826ab. In some embodiments, the conductive contact 818 is coupled to a single transistor 811 (e.g., the third transistor 811c) by an interconnect structure 826c. In some embodiments, the conductive contact 818 is coupled in series to at least two transistors 811 (e.g., the third transistor 811c and the fourth transistor 811d), by the interconnect structure 826c and an interconnect structure 826cd. In some embodiments, the conductive contact 818 is coupled in series to at least three transistors 811 (e.g., the third transistor 811c, the fourth transistor 811d, and the fifth transistor 811e), by interconnect structures 826c, 826cd and 826de. The several interconnect structure embodiments may be useful such as during test of a control circuitry (e.g., CMOS circuitry) of a microelectronic device, such as the microelectronic devices illustrated in any of FIGS. 1, 3, 4, 6 and 10.

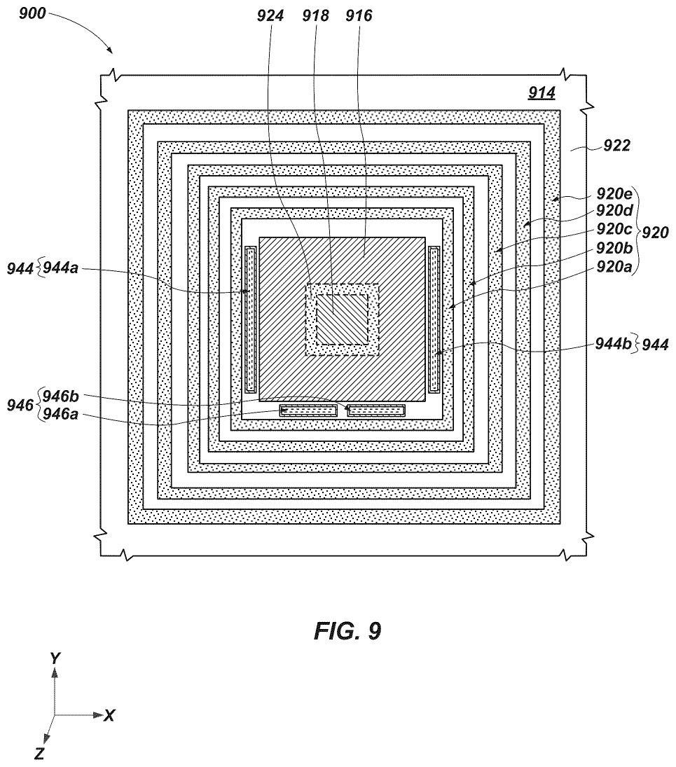

FIG. 9 is a simplified, top plan view of a microelectronic device 900, according to some embodiments. The microelectronic device 800 includes a bond pad 916, a corresponding conductive contact 918 several dielectric-filled slits 920 (e.g., dielectric-filled slits 920a, 920b, 920c, 920d and 920c), and contact structures 944 and 946. The conductive contact 918 and the contact structures 944 and 946 may vertically extend from a backside 914 of a control circuitry structure. A dielectric-filled slits 920 and base semiconductor material 922 are represented proximate to the bond pad 916. The conductive contact 918 and a dielectric liner 924 are illustrated using dashed lines since they are below the bond pad 916.

Still referring to FIG. 9, in some embodiments, extended contact structures 944 (e.g., extended contact structures 944a and 944b) may be horizontally spaced apart from the bond pad 916. The extended contact structures 944 may individually have length in the Y-direction that is at least more than half a horizontal edge dimension in the Y-direction of the bond pad 916. In addition, grouped contact structures 946 (e.g., grouped contact structures 946a and 946b) may horizontally extend in series with one another along an individual horizontal edge of the bond pad 916. In some embodiments, the extended contact structures 944 and/or the grouped contact structures 946 vertically extend from a memory array structure to the bond pad 916. The extended contact structures 944 and/or the grouped contact structures 946 may be useful such as during test operations of any of a microelectronic device, such as any of those illustrated in any of FIGS. 1, 3, 4, 6 and 10.

FIG. 10 is a simplified, partial transverse elevational view of a microelectronic device 1000 in an integrated circuit package 1001, according to some embodiments. The microelectronic device 1000 includes a control circuitry structure 1010, a memory array structure 1030, and at least one conductive contact 1018 located vertically below and within a horizontal area of an array edge region 1035 of the memory array structure 1030. The control circuitry structure 1010 includes an active region 1012 that includes transistors, sub-circuitry, and other circuitry; and the control circuitry structure 1010 also includes a backside 1014. The active region 1012 may be contained within a base structure of the microelectronic device 1000 within the control circuitry structure 1010, and the base structure may include at least one control logic region including control logic devices configured to control various operations of other features (e.g., strings of memory cells 1032 within an array region 1034) of the microelectronic device 1000.

A bond pad 1016 is coupled to a printed wiring board 1068 at an electrical bump that also contacts a bond pad 1066 on the printed wiring board 1068. The bond pad 1016 on the backside 1014 is coupled to circuitry of the active region 1012 of the control circuitry structure 1010 by way of at least one conductive contact 1018. The conductive contact 1018 is horizontally circumscribed by one or more dielectric-filled slits 1020 (e.g., dielectric-filled slits 1020a, 1020b and 1020c) that vertically extend through a base semiconductor material 1022 of the control circuitry structure 1010. The several dielectric-filled slits 1020 surround the conductive contact 1018, such that concentric “frame” (2D view) form factors, or concentric “fence” (3D view) form factors of dielectric-filled slits 1020 surround the conductive contact 1018. Consequently, the series of dielectric-filled slits 1020 (at least two (2)) facilitate a series capacitance with respect to capacitance experienced at each of the bond pad 1016 and the conductive contact 1018, such that the series capacitance reduces overall capacitance. Further, useful high-speed interconnectivity is available between the bond pad 1016 and a bridge die 1072 that may be embedded within a printed wiring board 1068. The bridge die 1072 may communicate between the microelectronic device 1000 and an additional microelectronic device 1070 (e.g., a processor die), for die-to-die data communication interconnections. The several dielectric-filled slits 1020 may reduce load capacitance during inter-die communication through the bridge die 1072.

Still referring to FIG. 10, the conductive contact 1018 may be surrounded by a dielectric liner 1024. In some embodiments, only two dielectric-filled slits 1020 horizontally surround the conductive contact 1018. In additional embodiments, three dielectric-filled slits 1020 horizontally surround the conductive contact 1018. In further embodiments, up to five dielectric-filled slits 1020 horizontally surround at least one conductive contact 1018. Communication between the conductive contact 1018 and circuitry of the control circuitry structure 1010 may be facilitated by way of interconnect structures 1026, such as traces. Several transistors may be included in the sub-circuitry and other circuitry of the control circuitry structure 1010. In some embodiments, the conductive contact 1018 penetrates the base semiconductor material 1022. The conductive contact 1018 may couple to at least one transistor 1011 vertically offset from the array edge region 1035. The transistor 1011 may be horizontally neighbor the conductive contact 1018, and several transistors 1011 may be horizontally separated from one another by insulative material 1009.

Similar to the microelectronic device 300 in FIG. 3, the microelectronic device 1000 is illustrated in simplified detail, with the strings of memory cells 1032 depicted in the array region 1034. Further the memory array structure 1030 includes an additional backside 1015 that is opposite the additional active region 1013, and an interconnect region 1036.

Still referring to FIG. 10, the integrated circuit package 1001 allows for high data rate transfer through the embedded bridge die 1072, between the microelectronic device 1000 and the additional microelectronic device 1070, where series capacitance is decreased at the conductive contact 1018 by use of the several dielectric-filled slits 1020. In some embodiments where the associated microelectronic device 1070 is flip-chip mounted on the printed wiring board 1068, an associated interconnect 1018Y may pass through a metallization structure 1074, where the associated interconnect 1018Y may also include dielectric-filled slit structures 1020Y to facilitate similar diminished capacitance behavior during high-speed data transfers. In some embodiments, the bond pads 1066 and 1066Y may have a size and a pitch that facilitates data transfer through the embedded bridge die 1072, and other bond pads 1076 and 1076Y may be differently sized and/or differently pitched according to useful flip-chip interconnections to the printed wiring board 1068.

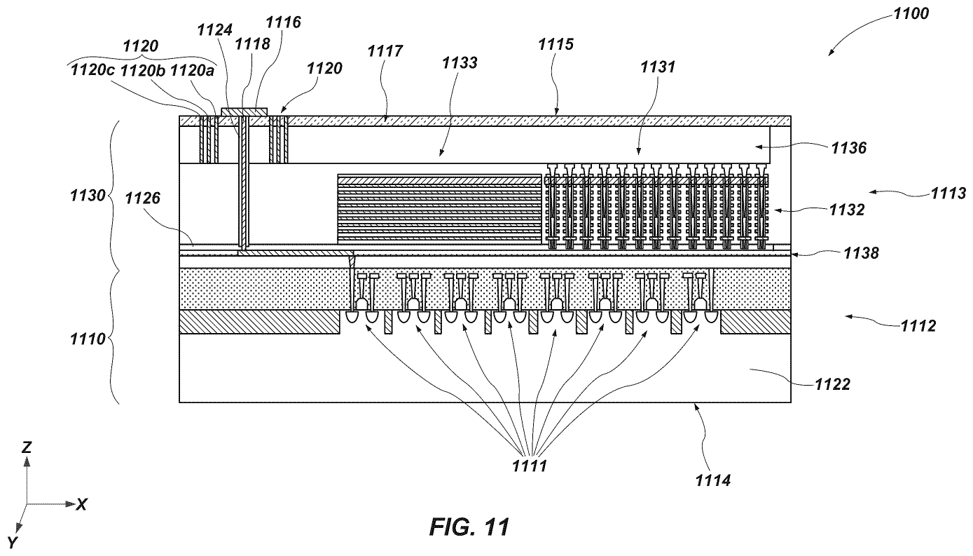

FIG. 11 is a simplified transverse cross-section elevation view of a microelectronic device 1100 (e.g., a memory device, such as a 3D NAND Flash memory device) including a control circuitry structure 1110 (e.g., a control circuitry wafer) including control logic devices including control logic circuitry, such as complementary metal-oxide-semiconductor (CMOS) circuitry; and a memory array structure 1130 (e.g., a memory array wafer) including at least one array of memory cells. In some embodiments, the microelectronic device 100 may be characterized as having a “CMOS under Array” (“CuA”) configuration, where the memory array structure 1130 and the control circuitry structure 1110 are assembled at an interface 1138.

The control circuitry structure 1110 may be attached (e.g., bonded) to the memory array structure 1130 in a so-called “wafer-to-wafer” (W2 W) configuration. The control circuitry structure 1110 includes an active region 1112 that having control logic devices individually including transistors 1111 and additional circuitry; and a bottom side 1114 opposite the active region 1112. The active region 1112 may be partially positioned within a base semiconductor material 1122 (e.g., bulk silicon material) of the microelectronic device 1100 located within the control circuitry structure 1110. The control logic devices of the active region 1112 may be configured to control various operations of other features (e.g., strings of memory cells within the memory array structure 1130) of the microelectronic device 1100. As a non-limiting example, the active region 1112 of the control circuitry structure 1110 may include one or more of the several functionalities set forth with respect to the functionalities described with reference to FIG. 1. The control logic devices of the active region 1112 of the control circuitry structure 1110 may be coupled to features (e.g., routing structures, contact structures, memory cells) within the memory array structure 1130 of the microelectronic device 1100.

The memory array structure 1130 has an additional active region 1113. The additional active region 1113 includes an array region 1131, where the array region 1131 includes strings of memory cells 1132 therein; and a staircase region 1133 horizontally neighboring the array region 1131 and including staircase structures therein. The memory array structure 1130 also includes an external boundary 1115 above (Z-direction) the additional active region 1113 and opposite the bottom side 1114 of the control circuitry structure 1110. With the active region 1112 of the control circuitry structure 1110 vertically positioned proximate to the additional active region 1113 of the memory array structure 1130, the microelectronic device 1100 may be considered to have a so-called “front-to-back” (F2B) configuration.

Still referring to FIG. 11, a bond pad 1116 on the external boundary 1115 (e.g., on the isolation material 1117 covering the interconnect region 1136) of the memory array structure 1130 is coupled to circuitry of the additional active region 1113 of the memory array structure 1130 by way of at least one conductive contact 1118 vertically extending through materials at the levels of the strings of memory cells 1132 as well as at the shared levels of a staircase region 1133. If the additional active region 1113 includes silicon, the at least one conductive contact 1118 may be a so-called “through silicon contact” (TSC) structure and/or a so-called “through silicon via” (TSV) structure. At least a portion of the conductive contact 1118 (e.g., a portion within vertical boundaries of the interconnect region 1136) may be substantially horizontally surrounded by the dielectric liner 1124. In addition, the memory array structure 1130 includes dielectric-filled slits 1120 within the additional active region 1113 and horizontally surrounding the conductive contact 1118. The dielectric-filled slits 1120 may vertically extend (e.g., in the Z-direction) at least through semiconductor material (e.g., silicon) of the interconnect region 1136 of the memory array structure 1130. In some embodiments, the dielectric-filled slits 1120 comprise slits filled with silicon oxide. The silicon oxide may be formed, at least in part, by oxidizing semiconductor material (e.g., silicon) of the interconnect region 1136 of memory array structure 1130. The several dielectric-filled slits 1120 vertically underlie the bond pad 1116 and horizontally surround the conductive contact 1118, such that in top view (e.g., similar to FIG. 2) the dielectric-filled slits 1120 appear as concentric “frame” (2D view) form factors, or concentric “fence” (3D view) form factors that horizontally surround the conductive contact 1118. As illustrated, the several dielectric-filled slits 1120 may include a first dielectric-filled slit 1120a, a second dielectric-filled slit 1120b having portions horizontally spaced apart from and horizontally extending parallel to the first dielectric-filled slit 1120a, and at least one subsequent dielectric-filled slit (in this illustration, a third dielectric-filled slit 1120c) having portions horizontally spaced apart from and horizontally extending parallel to the second dielectric-filled slit 1120b. The multiple (e.g., at least two (2)) dielectric-filled slits 1120 create a series capacitance with respect to capacitance experienced at each of the bond pad 1116 and the conductive contact 1118, such that the series capacitance reduces overall capacitance. In some embodiments, only two (2) dielectric-filled slits 1120 vertically underlie the bond pad 1116 and horizontally surround the conductive contact 1118. In additional embodiments, three dielectric-filled slits 1120 vertically underlie the bond pad 1116 and horizontally surround the conductive contact 118 below the bond pad 1116. In further embodiments, up to five (5) dielectric-filled slits 1120 vertically underlie the bond pad 1116 and horizontally surround the conductive contact 1118. Further, useful high-speed interconnectivity is available between the bond pad 1116 and the circuitry of the additional active region 1113 that facilitates functions such as testing and die-to-die data communication interconnections.

Communication between the conductive contact 1118 and circuitry of the memory array structure 1130 may be facilitated by way of routing structures 1126, such as traces. As illustrated, an individual routing structure 1126 may be coupled to an individual conductive contact 1118 and either CMOS circuitry in the control circuitry structure 1110 or within the memory array structure 1130.

In some embodiments, the dielectric-filled slits 1120 are in a different X-Z plane than that depicted in FIG. 11, such as in front of the depicted X-Z plane or behind the depicted X-Z plane. As illustrated at a cut-away section and in dashed lines, the conductive contact 1118 and the dielectric-filled slits 1120 that surround the conductive contact 1118 may be so located.

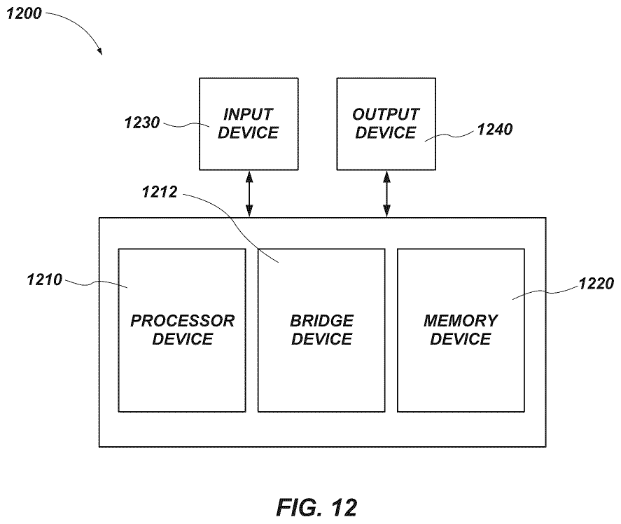

Microelectronic devices (e.g., the microelectronic device 100, the microelectronic device 300, the microelectronic device 400, the microelectronic device 600, the microelectronic device 1000, and the microelectronic device 1100) of the disclosure may be used in embodiments of electronic systems of the disclosure. For example, FIG. 12 is a block diagram of an electronic system 1200, according to embodiments of disclosure. The electronic system 1200 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, or a navigation device, etc. The electronic system 1200 includes at least one memory device 1220. The memory device 1220 may include, for example, one or more of the microelectronic devices (e.g., the microelectronic device 100, the microelectronic device 300, the microelectronic device 400, the microelectronic device 600, the microelectronic device 1000, and the microelectronic device 1100) of the disclosure. The electronic system 1200 may further include at least one electronic signal processor device 1210 (often referred to as a “microprocessor”) that is part of an integrated circuit. The electronic signal processor device 1210 may include, for example, one or more of microelectronic devices (e.g., the associated microelectronic device 1070 illustrated and described in FIG. 10) of the disclosure. While the memory device 1220 and the electronic signal processor device 1210 are depicted as two (2) separate devices in FIG. 12, in additional embodiments, a single (e.g., only one) memory/processor device having the functionalities of the memory device 1220 and the electronic signal processor device 1210 is included in the electronic system 1200. In such embodiments, the memory/processor device may include, for example, one or more of the microelectronic devices (e.g., the microelectronic device 100, the microelectronic device 300, the microelectronic device 400, the microelectronic device 600, the microelectronic device 1000, and the microelectronic device 1100) of the disclosure. The electronic signal processor device 1210 and the memory device 1220 may be part of a disaggregated-die assembly 1210 and 1220. The disaggregated-die assembly 1210 and 1220 may be coupled among the electronic signal processor device 1210 and the memory device 1220 by an embedded multi-die silicon bridge 1212 such as the embedded bridge die 1072.

The electronic system 1200 may further include one or more input devices 1230 for inputting information into the electronic system 1200 by a user, such as, for example, a mouse or other pointing device, a keyboard, a touchpad, a button, or a control panel. The electronic system 1200 may further include one or more output devices 1240 for outputting information (e.g., visual or audio output) to a user such as, for example, a monitor, a display, a printer, an audio output jack, and/or a speaker. In some embodiments, the input device 1230 and the output device 1240 may comprise a single touchscreen device that can be used both to input information to the electronic system 1200 and to output visual information to a user. The input device 1230 and the output device 1240 may electrically communicate with one or more of the memory devices 1220 and the electronic signal processor device 1210.

Thus, disclosed is a microelectronic device, comprising: a control circuitry structure comprising an active region including control logic circuitry at least partially within a semiconductive material; a bond pad on a backside of the control circuitry structure; a conductive contact vertically extending from the bond pad, through the semiconductive material, and to the control logic circuitry; and a dielectric-filled slit vertically extending into the semiconductive material and horizontally circumscribing the conductive contact, portions of the semiconductive material horizontally interposed between the conductive contact and the dielectric-filled slit.

Also disclosed is a memory device, comprising: a control circuitry structure comprising control logic devices; a memory array structure bonded to a first side of the control circuitry structure and comprising an array of memory cells; a bond pad overlying a second side of the control circuitry structure opposite the second side; one or more conductive contacts vertically extending from the bond pad, through semiconductive material of the control circuitry structure, and to at least some of the control logic devices of the control circuitry structure; and dielectric structures horizontally circumscribing the one or more conductive contacts and vertically extending partially through the semiconductive material of the control circuitry structure from a vertical boundary of the one or more conductive contacts, portions of the semiconductive material horizontally intervening between the one or more conductive contacts and the dielectric structures.

Also disclosed is an electronic system electronic system, comprising: an input device; an output device; a processor device operably coupled to the input device and the output device; and a memory device operably coupled to the processor device, the memory device comprising: a control circuitry wafer comprising an active region including complementary metal-oxide-semiconductive (CMOS) circuitry partially within semiconductive material; a memory array wafer oxide-oxide bonded to the control circuitry wafer and comprising an array of vertically extending strings of memory cells; a conductive pad on a backside of the control circuitry wafer distal from the memory array wafer; a conductive contact in electrical communication with the CMOS circuitry of the control circuitry wafer and the conductive pad, the conductive contact vertically extending completely through the semiconductive material of the control circuitry wafer; and dielectric liner material substantially covering sidewalls of the conductive contact; and dielectric structures vertically extending into the semiconductive material of the control circuitry wafer and substantially horizontally surrounding the dielectric liner material.

Also disclosed is a microelectronic device package, comprising: a printed wiring board; a bridge die at least partially embedded in the printed wiring board; a 3D NAND Flash memory device on the printed wiring board, the 3D NAND Flash memory device comprising: a control circuitry structure having a front side and a backside, the control circuitry structure comprising control logic devices; a memory array structure attached to the front side control circuitry structure and comprising vertically extending strings of memory cells; a conductive pad on backside of the control circuitry structure; a conductive contact extending from the conductive pad substantially through the control circuitry structure; and dielectric-filled slits vertically extending from the backside of the control circuitry structure and at least partially through semiconductive material of the control circuitry structure, the dielectric-filled slits individually horizontally offset from sidewalls of the conductive contact and substantially horizontally surrounding the conductive contact.

Also disclosed is a microelectronic device, comprising: a memory array structure comprising: strings of memory cells; and semiconductor material vertically overlying the strings of memory cells; a contact region horizontally offset from the strings of memory cells and comprising a portion of at semiconductive material; a bond pad on an external boundary of the memory array structure and positioned within the contact region of the memory array structure; a conductive contact vertically extending from the bond pad, through the portion of the semiconductive material, and to routing structures at least partially within the contact region and coupled to control logic circuitry operatively associated with the strings of memory cells; and a dielectric-filled slit vertically extending into the portion of the semiconductive material and horizontally circumscribing the conductive contact, a sub-portion of the portion of the semiconductive material horizontally interposed between the conductive contact and the dielectric-filled slit.

The disclosure advantageously facilitates one or more of improved microelectronic device performance, reduced costs (e.g., manufacturing costs, material costs), increased miniaturization of components, and greater packaging density as compared to conventional structures, conventional devices, conventional systems, and conventional methods. The structures, devices, systems, and methods of the disclosure may also improve scalability, efficiency, and simplicity as compared to conventional structures, conventional devices, conventional systems, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalents. For example, elements and features disclosed in relation to one embodiment of the disclosure may be combined with elements and features disclosed in relation to other embodiments of the disclosure.

What is claimed is:

1. A microelectronic device, comprising:
a control circuitry structure comprising an active region including control logic circuitry at least partially within a semiconductive material;
a bond pad on a backside of the control circuitry structure;
a conductive contact vertically extending from the bond pad, through the semiconductive material, and to the control logic circuitry; and
a dielectric-filled slit vertically extending into the semiconductive material and horizontally circumscribing the conductive contact, portions of the semiconductive material horizontally interposed between the conductive contact and the dielectric-filled slit.

2. The microelectronic device of claim 1, further comprising a dielectric liner horizontally surrounding the conductive contact, the dielectric liner horizontally interposed between the conductive contact and the portions of the semiconductive material.

3. The microelectronic device of claim 1, further comprising a memory array structure vertically offset from the control circuitry structure and comprising vertically extending strings of memory cells in electrical communication with at least some of the control logic circuitry.

4. The microelectronic device of claim 3, wherein transistors of the control logic circuitry are vertically interposed between and horizontally offset from the dielectric-filled slit and the vertically extending strings of memory cells.

5. The microelectronic device of claim 3, further comprising at least one additional dielectric-filled slit vertically extending into the semiconductive material and horizontally circumscribing the dielectric-filled slit, additional portions of the at least one additional dielectric-filled slit and the dielectric-filled slit.

6. The microelectronic device of claim 5, wherein the at least one additional dielectric-filled slit comprises two or more dielectric-filled slits, one of the two or more dielectric-filled slits horizontally circumscribing another one of the two or more dielectric-filled slits.

7. The microelectronic device of claim 3, wherein the memory array structure is attached to the control circuitry structure through oxide-oxide bonding.

8. The microelectronic device of claim 1, wherein the dielectric-filled slit is positioned outside of a horizontal area of the bond pad.

9. The microelectronic device of claim 1, wherein a horizontal center of the conductive contact is substantially aligned with a horizontal center of the bond pad.

10. The microelectronic device of claim 1, further comprising an additional conductive contact vertically extending from the bond pad, through the semiconductive material, and to the control logic circuitry, horizontal centers of the conductive contact and the additional conductive contact offset from a horizontal center of the bond pad.

11. The microelectronic device of claim 10, wherein:
the conductive contact and the additional conductive contact are coupled to different portions of the control logic circuitry of the control circuitry structure than one another.

12. The microelectronic device of claim 10, wherein the dielectric-filled slit horizontally circumscribes each of the conductive contact and the additional conductive contact.

13. A memory device, comprising:
a control circuitry structure comprising control logic devices;
a memory array structure bonded to a first side of the control circuitry structure and comprising an array of memory cells;
a bond pad overlying a second side of the control circuitry structure opposite the second side;
one or more conductive contacts vertically extending from the bond pad, through semiconductive material of the control circuitry structure, and to at least some of the control logic devices of the control circuitry structure; and
dielectric structures horizontally circumscribing the one or more conductive contacts and vertically extending partially through the semiconductive material of the control circuitry structure from a vertical boundary of the one or more conductive contacts, portions of the semiconductive material horizontally intervening between the one or more conductive contacts and the dielectric structures.

14. The memory device of claim 13, wherein the at least one of the one or more conductive contacts is positioned outside of a horizontal area of the array of memory cells.

15. The memory device of claim 13, wherein at least one of the dielectric structures has a different horizontal cross-sectional shape than at least one other of the dielectric structures.

16. The memory device of claim 13, further comprising dielectric liner material directly adjacent and substantially covering side surfaces of the one or more conductive contacts.

17. The memory device of claim 13, wherein at least one of the dielectric structures is positioned outside of a horizontal area of the bond pad.

18. The memory device of claim 17, wherein:
at least one other of the dielectric structures is positioned within of a horizontal area of the bond pad;
the at least one other of the dielectric structures horizontally circumscribes the one or more conductive contacts; and
the at least one of the dielectric structures horizontally circumscribes the at least one other of the dielectric structures.

19. A microelectronic device, comprising:
a memory array structure comprising:
strings of memory cells; and
semiconductor material vertically overlying the strings of memory cells;
a contact region horizontally offset from the strings of memory cells and comprising a portion of at semiconductive material;
a bond pad on an external boundary of the memory array structure and positioned within the contact region of the memory array structure;
a conductive contact vertically extending from the bond pad, through the portion of the semiconductive material, and to routing structures at least partially within the contact region and coupled to control logic circuitry operatively associated with the strings of memory cells; and
a dielectric-filled slit vertically extending into the portion of the semiconductive material and horizontally circumscribing the conductive contact, a sub-portion of the portion of the semiconductive material horizontally interposed between the conductive contact and the dielectric-filled slit.

20. The microelectronic device of claim 19, further comprising a control circuitry structure comprising the control logic circuitry, the memory array structure and the control circuitry structure bonded to one another at an interface.
